(19) United States
(12) Patent Application Publication
(10) Pub. No.: US 2008/0054896 A1
(43) Pub. Date: Mar. 6, 2008

(54) Magnetic Sensor with Parallel Magnetic Sensor Strips

(75) Inventor: Josephus Arnoldus Henricus Maria Kahlman, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/719,856

(22) PCT Filed: Nov. 21, 2005
(86) PCT No.: PCT/IB05/53845

§ 371 Date: May 22, 2007

(30) Foreign Application Priority Data
Nov. 25, 2004 (EP) 04106095.5

(51) Int. Cl. G01R 33/06

(52) U.S. Cl. 324/252; 324/244

(57) ABSTRACT

The present provides a magnetic sensor device comprising at least one magnetic sensor element with N parallel magnetic sensor strips, N being at least 2, and wherein a constant voltage is applied across the N parallel magnetic sensor strips. The sensor device may advantageous be applied in applications where a large sensor surface with high uniform sensitivity is required.

The present invention relates to a device and method for the detection or determination of magnetic particles, such as for example, but not limited to, magnetic nanoparticles. In particular it relates to a magnetic sensor comprising parallel magnetic sensor strips and methods of operating the same.

Magneto-resistive sensors based on AMR (anisotropic magneto-resistance), GMR (giant magneto-resistance) and TMR (tunnel magneto-resistance) elements are nowadays gaining importance. Besides the known high speed applications such as magnetic hard disk heads and MRAM, new relatively low bandwidth applications appear in the field of molecular diagnostics (MDx), current sensing in IC's, automotive, etc.

One example of magneto-resistive sensors is a biochip. Biochips, also called biosensor chips, biological microchips, gene-chips or DNA chips, consist in their simplest form of a substrate on which a large number of different probe molecules are attached, on well defined regions on the chip, to which molecules or molecule fragments that are to be analyzed can bind if they are perfectly matched. For example, a fragment of a DNA molecule binds to one unique complementary DNA (c-DNA) molecular fragment. The occurrence of a binding reaction can be detected, e.g. by using fluorescent markers that are coupled to the molecules to be analyzed. This provides the ability to analyze small amounts of a large number of different molecules or molecular fragments in parallel, in a short time. One biochip can hold assays for 10-1000 or more different molecular fragments. It is expected that the usefulness of information that can become available from the use of biochips will increase rapidly during the coming decade, as a result of projects such as the Human Genome Project, and follow-up studies on the functions of genes and proteins.

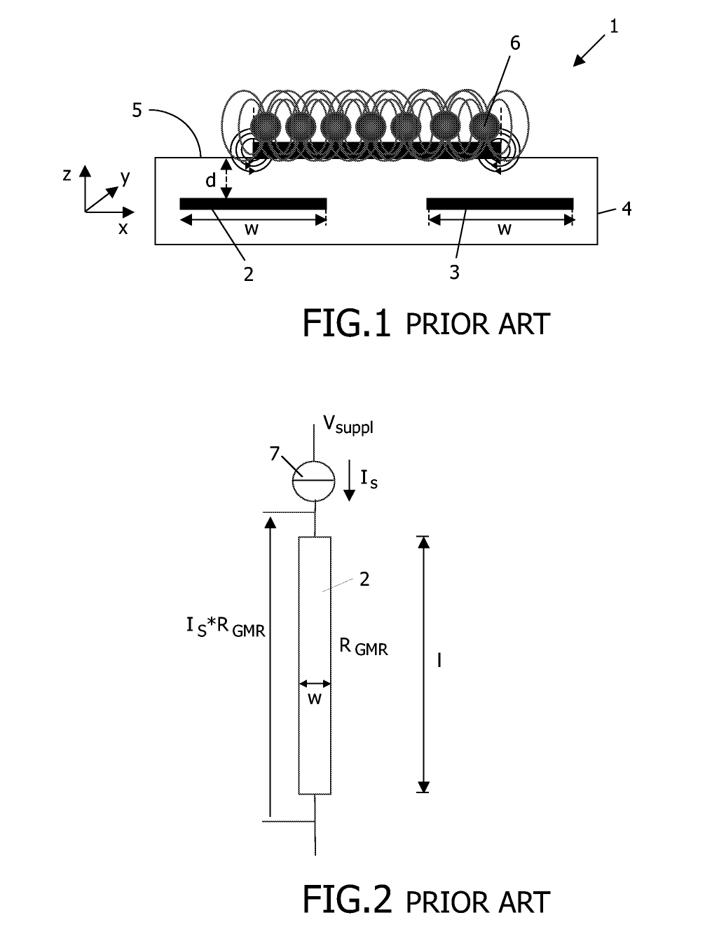

In WO 03/054523 a magnetic nanoparticle biosensor for the detection of biological molecules on a micro-array or biochip is disclosed, which sensor uses GMR sensor elements. A magneto-resistive sensor 1, as described in one embodiment of the cited document, is illustrated in FIG. 1. The sensor 1 comprises a first GMR sensor element 2 and a second GMR sensor element 3 integrated in a biochip substrate 4 at a distance d under the surface 5 of the substrate 4. The surface 5 of the biochip substrate 4 has to be modified in order to allow nanoparticles 6 to bind to it.

In FIG. 1 a co-ordinate system has been introduced and according to that coordinate system, the first and second GMR elements 2, 3 extend in the y direction over a certain length. If the magneto-resistive sensor elements 2, 3 lie in the xy-plane, the GMR sensor elements 2, 3 mainly detect the x-component of the magnetic field, i.e. they have a sensitive direction in the x-direction. In order to read out the biochip, the super-paramagnetic nanoparticles 6 bound to it are magnetized by an external, uniform magnetic field perpendicular to the plane of the biochip. The perpendicular magnetic field orientates the higher magnetic field at the ends of the magnetic dipoles formed by the nanoparticles 6 towards and close to the first and second GMR sensor elements 2, 3. The magnetized nanoparticles 6 produce regions of opposite magnetic induction vectors in the plane of the underlying GMR films and the resulting magnetic field is detected by the first and second GMR sensor elements 2, 3. The outputs of the GMR sensor elements 2, 3 are fed to a comparator.

Generally speaking, the signal-to-noise ratio (SNR) of a GMR sensor, which is the ratio between the signal power and the noise power, is proportional to the area of the strip, thus:

SNR ∝ l.w

wherein l is the length and w is the width of the GMR sensor.

Increasing the length of the GMR sensor element 2, 3 will increase the SNR but consequently also the required supply voltage. This is hardly compatible with applications where the GMR sensors and signal processing circuitry are combined on an integrated circuit.

In many applications it is beneficial to increase the sensor length l. The geometry of the magneto-resistive sensor 1 proposed in WO 03/054523 is such that the sensitivity is maximal at the edges of the sensor strip. Consequently, increasing the width of the strip does not gain SNR and the only way to improve the SNR is by increasing the sensor length. Furthermore, a large sensor area will increase the number of bonded nanoparticles and therefore reduce the noise of the binding process.

A problem arises from the fact that increasing the length of the sensor elements 2, 3 and thus increasing the length l of the magneto-resistive sensor 1 will also increase the resistance of the magneto-resistive sensor 1:

$${R}_{GMR} = {R}_{sq} \cdot \frac{1}{w}$$

wherein R_{GMR} is the resistance of a particular magneto-resistive sensor 1, and R_{sq} is the sheet resistance of the magneto-resistive material used for the GMR sensor elements 2, 3.

Given a constant sense-current Iₛ, applied by means of current source 7 (see FIG. 2), the required supply voltage Vₛᵤₚₚₗ will increase with increasing resistance of the magneto-resistive sensor 1. This is particularly problematic in integrated circuits because the IC process limits the maximum available supply voltage. Furthermore the maximum voltage across a GMR sensor is also limited.

It is an object of the present invention to provide a magneto-resistive sensor and a method for the detection or determination of magnetic particles, which require reduced supply voltage and/or show a reduced sensitivity to the binding distribution of magnetic particles on the sensor surface.

The above objective is accomplished by a method and device according to the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

The present invention provides a sensor device comprising at least one magnetic sensor element and at least one magnetic field generating means for generating a magnetic field. According to the invention, the at least one magnetic sensor element comprises a plurality of N parallel magnetic sensor strips, N being at least 2, and the sensor device furthermore comprises a voltage source for applying a constant voltage over the at least one magnetic sensor element. According to embodiments of the present invention, the magnetic sensor strips may be magneto-resistive sensor strips, such as, for example, GMR, TMR or AMR sensor strips.

In the sensor device according to the present invention, the total measuring signal as a result of magnetic particles in the vicinity of the sensor device will change proportionally with the amount of magnetic particles, regardless of whether the magnetic particles are uniformly or non-uniformly distributed over the different sensor strips of the sensor element. As a result, the total measuring signal is thus not affected by the binding distribution of the magnetic particles on the separate magnetic sensor strips.

The sensor element according to the invention may be implemented with either an on-chip or an off-chip magnetic field generating means. Furthermore, the device according to the invention may be applied advantageously when a large sensor surface with high uniform sensitivity is required.

The magnetic sensor element may be positioned on a substrate and the sensor device may furthermore comprise a signal processing means, positioned on the same substrate as the magnetic sensor element. In an embodiment of the invention, the magnetic sensor element, the signal processing means and the magnetic field generating means may form an integrated circuit. The signal processing means may comprise at least one amplifier. In another embodiment, the signal processing means may furthermore comprise a linearizing circuit. The linearizing circuit has the functionality to correct for a non-linear R-H characteristic of the sensor elements.

In one embodiment, the magnetic field generating means may comprise a conductor and an alternating current source for generating an alternating current flowing through the conductor.

In a specific embodiment of the invention, the sensor device may comprise two magnetic sensor elements, each comprising N parallel magnetic sensor strips, N being at least 2.

According to the invention, the sensor device may furthermore comprise means for measuring a current flowing through the at least one magnetic sensor element.

The present invention furthermore provides a method for the detection of the presence or determination of magnetic particles. The method comprises the steps of:

generating a magnetic field in the vicinity of a magnetic sensor element, the magnetic sensor element comprising a plurality of N parallel magnetic sensor strips,

applying a constant voltage across the magnetic sensor element, and

measuring a total signal current is in the magnetic sensor element.

In an embodiment according to the invention, generating a magnetic field may be performed by a magnetic field generator comprising a conductor and a current source for generating a current through the conductor.

By applying the detection method according to the present invention the low frequency magnetic noise as well as low frequency electronic noise, drift and offset are suppressed.

The present invention furthermore includes the use of a sensor device according to the invention for molecular diagnostics, biological sample analysis, or chemical sample analysis.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention.

The reference Figures quoted below refer to the attached drawings.

FIG. 1 is a cross-section of part of a magneto-resistive sensor comprising GMR sensor elements, according to the prior art.

FIG. 2 shows a current driven long GMR strip according to the prior art.

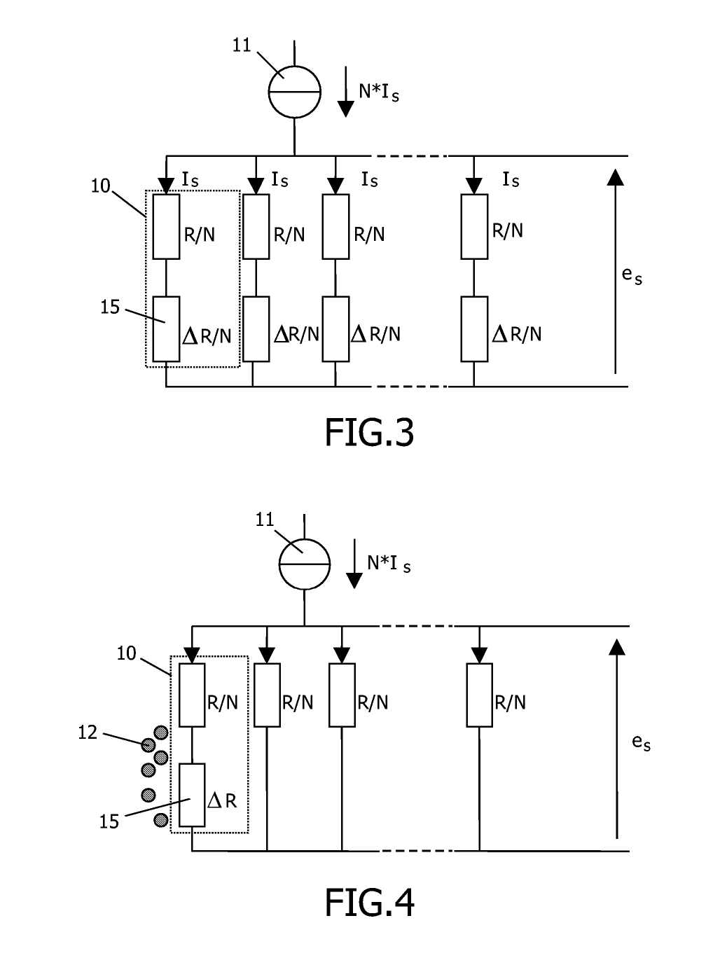

FIG. 3 shows current driven parallel sensor strips according to a non-preferred solution to the problem to be solved.

FIG. 4 shows the particular case of current driven parallel sensor strips as in FIG. 3, where all magnetic particles are concentrated on one single strip.

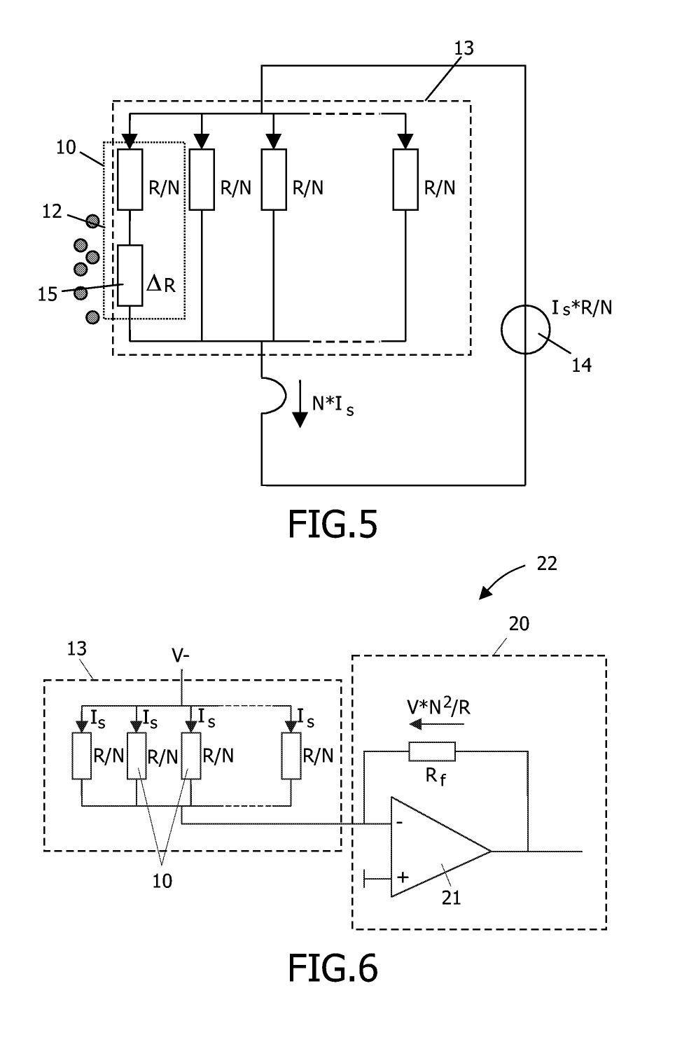

FIG. 5 shows parallel sensor strips powered by a voltage source according to an embodiment of the present invention.

FIG. 6 shows a schematic representation of a biosensor device according to an embodiment of the present invention.

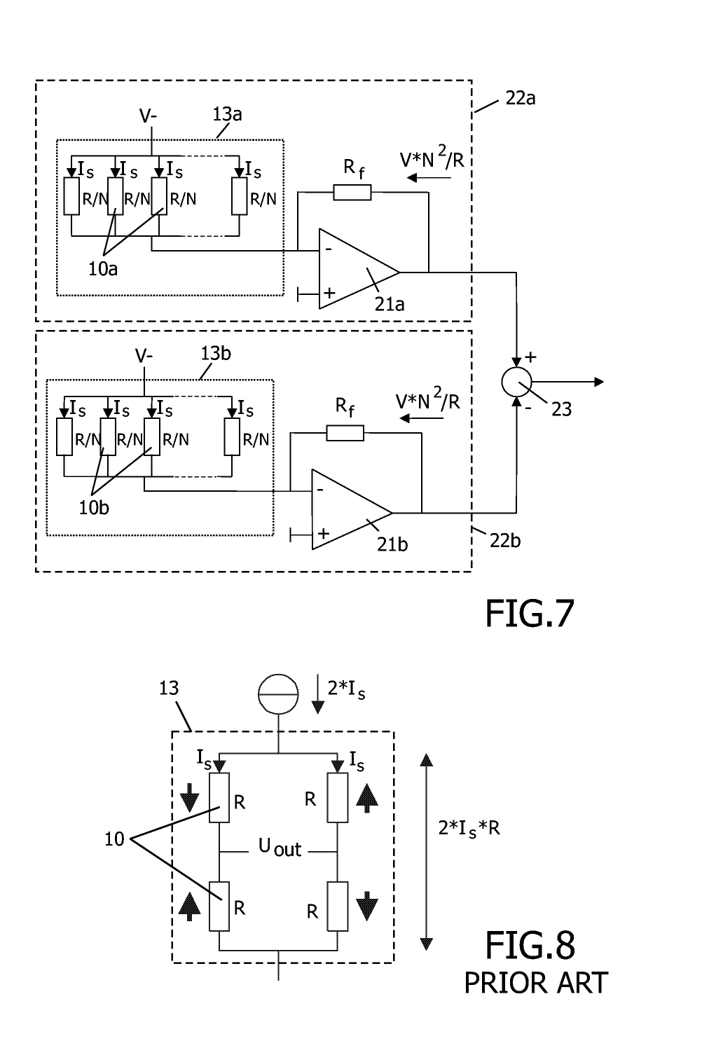

FIG. 7 illustrates a bridge configuration of first and second OpAmp circuits according to an embodiment of the present invention.

FIG. 8 illustrates a prior art full Wheatstone bridge configuration in a sensor device.

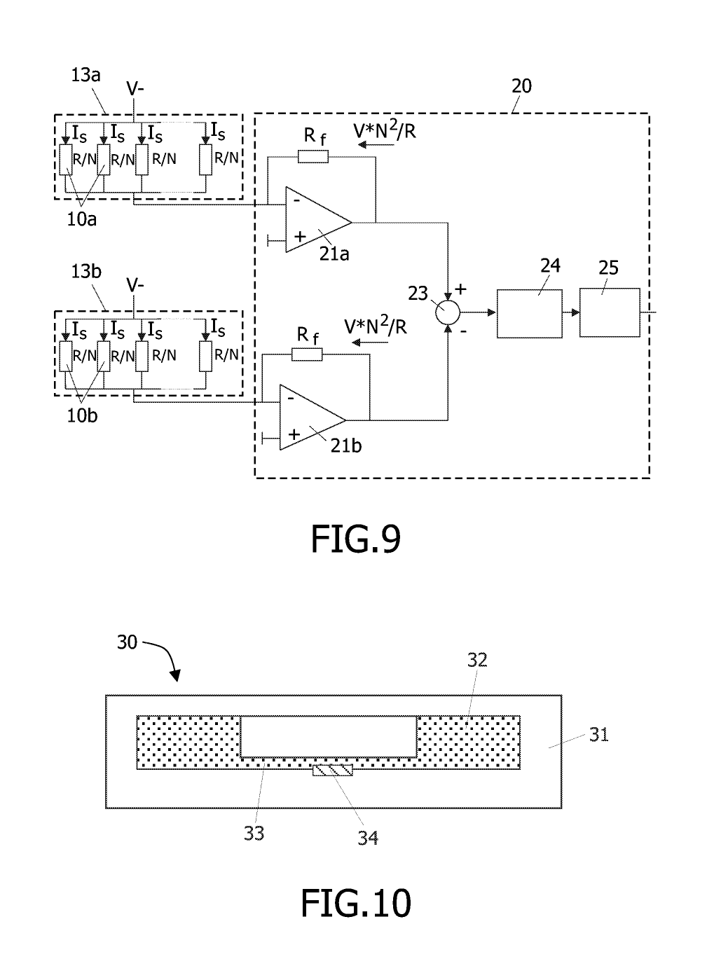

FIG. 9 illustrates a sensor configuration according to an embodiment of the present invention, suitable for being implemented in an integrated circuit.

FIG. 10 shows a schematic representation of a biosensor device according to an embodiment of the present invention.

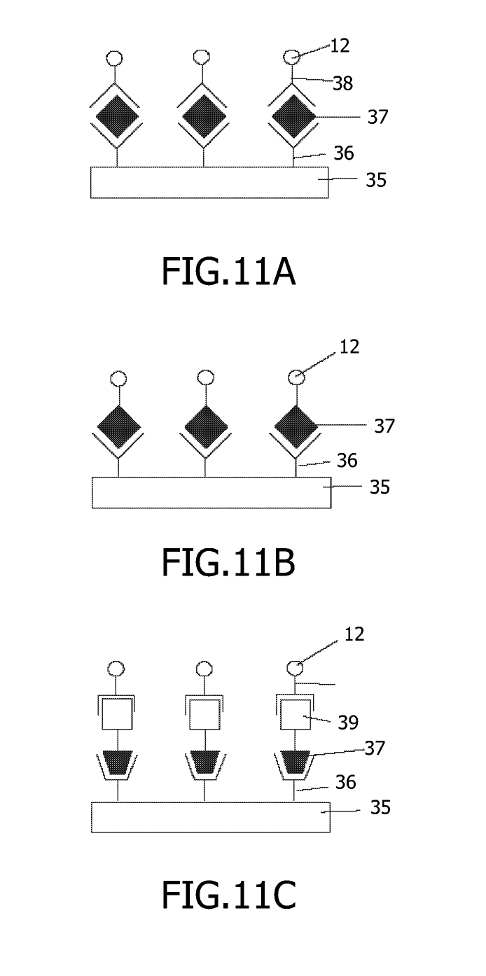

FIGS. 11A, 11B and 11C show details of a probe element provided with binding sites able to selectively bind target sample, and magnetic nanoparticles being directly or indirectly bound to the target sample in different ways.

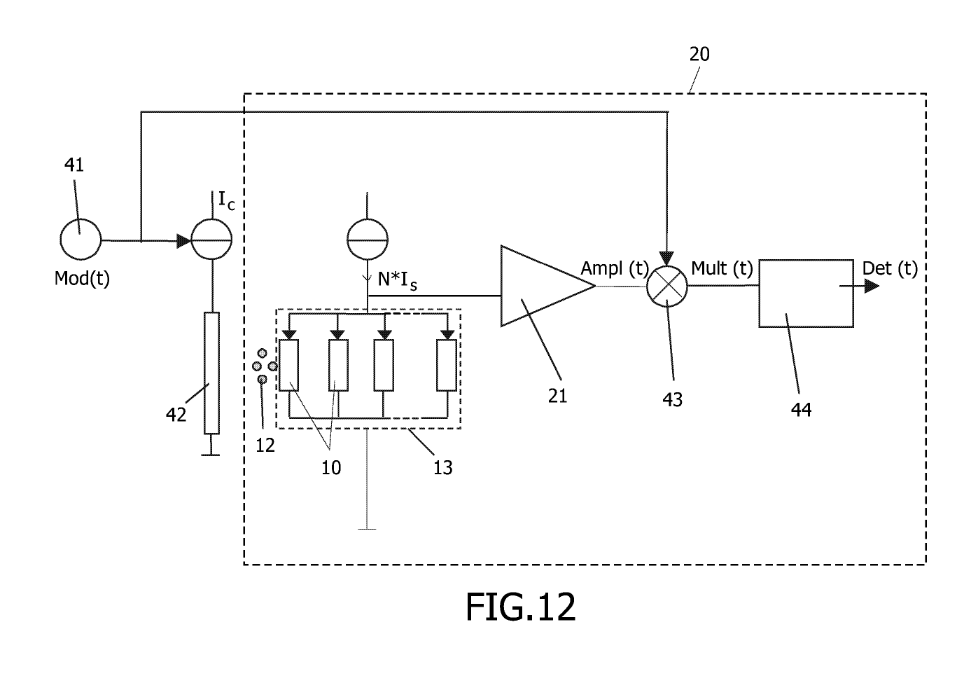

FIG. 12 is a schematic view of a detection method according to an embodiment of the present invention.

In the different Figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

It is furthermore to be noticed that the term “comprising”, used in the description and in the claims, should not be interpreted as being restricted to the means listed thereafter; it does not exclude other elements or steps. Thus, the scope of the expression “a device comprising means A and B” should not be limited to devices consisting only of components A and B. It means that with respect to the present invention, the only relevant components of the device are A and B.

As already mentioned in the background section, the prior art sensors show the drawback that, by increasing the length of the sensor element 2 for achieving an improved SNR, also the sensor resistance R_{GMR} is increased, which leads, with a constant sense current Iₛ being provided by current source 7, to an increase of the required supply voltage (see FIG. 2).

One solution to this problem, however not preferred, could be to divide the total magneto-resistive sensor element 2 into a plurality of N magneto-resistive sensor strips 10, each representing a resistance R/N to which a constant sense current Iₛ is provided by a current source 11. However, current driven parallel GMR or TMR sensor strips 10 have the drawback that the total sensor signal depends on the distribution of magnetic particles 12 across the sensor strips 10. Therefore, in case of a non-uniform distribution of magnetic particles 12 across the different sensor strips 10, the strips 10 do, in that case, not all have the same change in resistance ΔR. Hence, the total resistance and thus the total sensor signal eₛ will depend on the distribution of the magnetic particles 12 over the different sensor strips 10. The magnetic particles 12 can have small dimensions and may for example be nanoparticles. With nanoparticles are meant particles having at least one dimension ranging between 0.1 nm and 1000 nm, preferably between 3 nm and 500 nm and more preferred between 10 nm and 300 nm. The magnetic particles 12 can acquire a magnetic moment due to an applied magnetic field (e.g. they can be paramagnetic) or they can have a permanent magnetic moment. The magnetic particles 12 can be a composite, e.g. consist of one or more small magnetic particles inside or attached to a non-magnetic material. As long as the particles 12 generate a non-zero response to the frequency of an ac magnetic field, i.e. when they generate a magnetic susceptibility or permeability, they can be used.

In FIG. 3 a situation is illustrated where magnetic particles 12 are distributed equally over the sensor strips 10 of a sensor device. In the absence of magnetic particles 12, each sensor strip 10 shows a resistance R/N. When equal amounts of magnetic particles are present at the surface of each of the sensor strips 10, the resistance of each of these sensor strips 10 changes with a value ΔR/N, which is schematically illustrated by reference numeral 15 in FIG. 3. The resistance of each of the sensor strips 10 thus changes to

$${R}_{GMR} = ( R + Δ R ) \cdot \frac{1}{N} .$$

Because the resistance of each sensor strip 10 is equal, a same current Iₛ flows through each of the sensor strips 10. As a result, the effective sensor signal measured across the sensor device due to the presence of the equal distributed particles 12 equals

$${e}_{s} = {I}_{s} \frac{Δ R}{N} .$$

If in one specific situation, which is a worst-case situation, all magnetic particles 12 would be concentrated on one single sensor strip 10 (as illustrated in FIG. 4), the effective sensor signal eₛ, which is the voltage changed due to the presence of magnetic particles, would equal to:

$${e}_{s} = {I}_{s} \frac{Δ R}{N} \cdot \frac{1}{1 + ( N - 1 ) \frac{Δ R}{R}}$$

When assuming N=10 and ΔR/R=0.04, the effective sensor signal has diminished to 73% compared to uniformly distributed magnetic particles 12.

Therefore, according to an aspect of the present invention, a solution to this problem is to set up a magnetic sensor element 13 as a plurality N, N being at least two, of parallel separate magnetic sensor strips 10. The number of parallel sensor strips 10 forming the sensor element 13 is not restricted. However, when the resistance of the sensor element 13 is too low, e.g. below 10 ohm, it may become impossible to implement a pre-amplifier having a noise floor under the thermal noise of the sensor.

Across these magnetic sensor strips 10, and thus across magnetic sensor 13, a constant voltage, provided by a voltage source 14, is applied (see FIG. 5). The magnetic sensor strips 10 may for example be magneto-resistive sensor strips such as e.g. AMR, GMR or TMR sensor strips.

Thus, the voltage drop over each sensor strip 10 is constant and the total current through the sensor element 13 is measured. The total signal current iₛ then equals to the sum of the current in each sensor. Hence, the total signal current iₛ will change proportionally with the amount of magnetic particles 12, regardless of whether the magnetic particles 12 are uniformly or non-uniformly distributed over the different sensor strips 10 of the sensor element 13. As a result, the total measuring signal (in the present case the current) is thus not affected by the binding distribution of the magnetic particles 12 on the separate magnetic sensor strips 10. The total sensor signal is represented by the signal current iₛ=N*Iₛ.

An advantage of increasing the sensor length and dividing the magnetic sensor element 13 into separate magnetic sensor strips 10 is that it enables SNR (signal to noise ratio) enhancement without increasing the supply voltage. This makes effectively long sensor strips 10 compatible with low voltage IC processes. Another advantage is that the total sensor signal is independent of the binding distribution of magnetic particles 12 on the sensor strips 10.

FIG. 6 illustrates a possible signal processing means 20 which may be used according to the present invention and which, in this embodiment, may comprise an amplifier such as an operational amplifier (OpAmp) 21 for amplifying the sensor signal when the magnetic sensor element 13 is used in a sensor device, such as for example a biosensor (see further). Therefore, in this embodiment, the magnetic sensor element 13 comprises N parallel magnetic sensor strips 10 together with the signal processing means 20 comprising OpAmp circuit 22. The magnetic sensor element 13 and the signal processing means 20 are positioned on a same substrate (not shown in the Figures). In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass, plastic or metal layer.

It has, however, to be understood that FIG. 6 is only an example of a possible signal processing means 20 that may be used according to the invention and is not limiting to the invention. The signal processing means 20 may for example comprise more than one OpAmp 21 or may furthermore comprise other functionalities (see further).

In another embodiment of the invention, a half bridge configuration of a first and a second amplifier, e.g. OpAmp circuits 21a resp. 21b is provided. This is illustrated in FIG. 7. By using such a half bridge configuration, temperature effects and the influence of common mode disturbing magnetic fields can be removed. For example, a magnetic field may be applied to the sensor strips 10a of the first OpAmp circuit 21a by means of e.g. a conductor. The signal of the first OpAmp circuit 21a is sent to adder 23. No magnetic field is applied to the sensor strips 10b of the second OpAmp circuit 21b. The signal that is sent from the second OpAmp circuit 21b to the adder 23 only comprises noise coming from the sensor strips. The signal of the second OpAmp circuit 21b is subtracted from the signal of the first OpAmp circuit 21a and the resulting signal can then be processed further. In that way, correction can be performed for the common mode disturbing magnetic field. As both parallel sensor elements 13a and 13b are close together on a same substrate, they are on the same temperature and they have the same temperature dependency R(T). Therefore, a temperature change will influence the signal from both parallel sensor elements 13a and 13b with the same amount, and the effect will cancel after subtraction. In other words, it is a common mode effect.

For reasons of linearizing the sensor characteristic, often a full Wheatstone bridge configuration, as is illustrated in FIG. 8, is used. As the Wheatstone bridge configuration requires four magnetic sensor strips 10 per sensor element 13, a disadvantage of the configuration is that it is area inefficient. Furthermore, the required supply voltage is doubled compared to the previous embodiment.

The same functionality, however, can be implemented by using the sensor configuration according to a further embodiment of the invention which is illustrated in FIG. 9. The sensor configuration may comprise two magnetic sensor elements 13a,b, each comprising N parallel magnetic sensor strips 10a,b, and a signal processing means 20. The signal processing means 20 may comprise two amplifiers 21a,b for amplifying the sensor signal. The signal processing means 20 may furthermore comprise an adder 23 for subtracting the signal coming from the second sensor element 13b from the signal coming from the first sensor element 13a. The signal processing means 20 may furthermore comprise an AD converter 24.

The signal processing means 20 may also comprise a linearizing unit 25 having the functionality to correct for a non-linear R-H characteristic of the sensor elements 13a,b. In this embodiment, the signals form the magnetic sensor elements 13a,b are amplified and converted to the digital domain. A digital circuitry corrects for the non-linear R-H curve of the magnetic sensor elements 13a,b. This can be implemented using a ROM-table or an arithmetical function having fixed or adaptive coefficients. The non-linearity of each magnetic sensor element 13a,b can be calibrated by applying a magnetic field to it and store the R-H characteristic or a measure for its inverse function (the correction) on the chip or substrate.

In the present embodiment, the linearizing function is implemented in the digital domain. However, in other embodiments, the linearizing function can also be implemented in the analogue domain by using for example non-linear elements like diodes.

It has to be understood that the sensor configuration as illustrated in FIG. 9 is only meant as an example and is not limiting to the invention. The sensor configuration may comprise more or less than two sensors 13a,b, more than one or no AD converter 24 and more than one linearizing functionality 25. A typical biosensor, for example, which will be described hereinafter, may comprise several, e.g. 100, magnetic sensor elements 13a,b which are, individually or in groups, multiplexed to the signal processing means 24.

For detecting the presence and/or concentration of magnetic particles 12 in the neighborhood of the sensor, a magnetic field has to be applied. This may be done by a magnetic field generating means, which may, in one embodiment, be positioned at the same substrate as the magnetic sensor element 13 and the signal processing means 20 and is called an on-chip magnetic field generating means. In that case, the magnetic sensor element 13, the signal processing means 20 and the magnetic field generating means can form an integrated circuit. In another embodiment, the magnetic field generating means may be positioned on a different substrate and is then called an off-chip magnetic field generating means.

Hence, the sensor element 13 according to the invention may be implemented with either an on-chip or an off-chip magnetic field generating means. Furthermore, the device according to the invention may be applied advantageously when a large sensor surface with high uniform sensitivity is required.

One example of a sensor device 30 in which the sensor element 13 according to the invention can be applied is a biosensor device 30 as illustrated in FIG. 10. The biosensor device 30 may comprise a cartridge housing 31, chambers 32 and/or channels 33 for containing the material, e.g. the analyte to be analyzed, and a biochip 34. The biochip 34 is a collection of miniaturized test sites, called micro-arrays, arranged on a solid substrate that permits many tests to be performed at the same time in order to achieve higher throughput and speed. It can be divided into tens to thousands of tiny chambers each containing bioactive molecules, e.g. short DNA strands or probes. In addition to genetic applications (e.g. decoding genes), the biochip 34 may be used in toxicological, protein, and biochemical research, in clinical diagnostics and scientific research to improved disease detection, diagnosis and ultimately prevention.

A biochip 34 comprises a substrate with at its surface at least one, preferably a plurality of probe areas. Each probe area comprises a probe element 35 over at least part of its surface. The probe element 35 is provided with binding sites 36, such as, for example including binding molecules or antibodies, able to selectively bind a target sample molecule 37 such as for example a target molecule species or an antigen. Any biologically active molecule that can be coupled to a matrix is of potential use in this application. Examples may be nucleic acids with or without modifications (e.g. DNA, RNA), proteins or peptides with or without modifications (e.g. antibodies, DNA or RNA binding proteins), oligo- or polysaccharides or sugars, small molecules such as inhibitors, ligands, cross-linked as such to a matrix or via a spacer molecule.

In FIG. 11A, sensor molecules 38 labeled with magnetic particles 14 are able to selectively bind target sample molecule 37. In this example, magnetic particles 15 are indirectly bound to the target sample 37. In FIG. 11B, the target sample molecules 37 are directly labeled by magnetic particles 14 and in FIG. 11C, target sample molecule 37 is labeled by labels 39 on the target sample molecule 37. Also in this case the magnetic particles 14 are indirectly bound to the target sample molecule 37.

The functioning of the biochip 34 is as follows. Each probe element 35 is provided with binding sites 36 of a certain type. Target sample molecules 37 are presented to or passed over the probe element 35, and if the binding sites 36 and the target sample molecule 37 match, they bind to each other. Magnetic particles 14 are directly or indirectly coupled to the target sample molecules 37, as illustrated in FIGS. 11A, 11B and 11C. The magnetic particles 14 allow read out of the information gathered by the biochip 34. To achieve this each binding site is separately addressable or readable.

The biosensor device 30 may be applied to detect magnetic particles 12 in a sample such as a fluid, a liquid, a gas, a visco-elastic medium, a gel or a tissue sample.

The biosensor device 30 may comprise a substrate and a circuit, e.g. an integrated circuit. The circuit may comprise at least one magnetic sensor 13 as described according to the present invention and at least one magnetic field generator in the form of e.g. a conductor.

It has, however, to be noted that the biosensor device 30 described hereinabove is only an example and that the generic solution provided by the present invention combines a low voltage IC process and GMR elements and that it therefore is not limited to be applied to these biosensors. The sensor device 30 according to the present invention may also be used in, for example, magnetic camera devices having uniform sensitivity per pixel or in MRAM where a magnetic entity may be sensed by parallel sensor elements 13a,b.

In FIG. 12 a method for detection of magnetic particles 12, applying the sensor element 13 with N parallel sensor strips 10 according to an embodiment of the present invention, is illustrated. A modulating signal Mod(t) having a suitable amplitude such as a sinusoidal wave (sin at) and with a frequency of, for example but not limited thereto, 50 kHz supplied by a source 41, is sent to a conductor 42 to modulate the conductor current I_{c}. With a high frequency, according to the present invention, is meant a frequency which does not generate a substantial movement of the magnetic particles 12 at that frequency, for example 100 Hz or higher, preferably 1 kHz or higher and more preferred 50 kHz or higher, up to e.g. 1 GHZ.

The conductor current is modulated by any suitable waveform, e.g. I_{c}=I_{c} sin at, and this modulated current induces a magnetic field which per se is mainly vertical or z-oriented at the location of the magnetic sensor strips 10.

A sensing current Iₛ passes through the magnetic sensor strips 10. Without the presence of magnetic particles 12, the input signal is the ac magnetic field from the conductor 42. Depending on the presence of nanoparticles 12 in the neighborhood of the magnetic sensor strips 10, the magnetic field at the location of the magnetic sensor strips 10, and thus the resistance of the magnetic sensor strips 10 is changed. The magnetic field Hₓ in the sensitive x-direction of the magnetic sensor strips 10 is to a first order proportional to the number Nₙₚ of magnetic particles 12 and the conductor current I_{c}.

Hₓ ∝ Nₙₚ I_{c} sin at.

A different resistance of the magnetic sensor strips 10 leads to a different voltage drop over the sensor strips 10, and thus to a different measurement signal delivered by the magnetic sensor element 13.

The measurement signal delivered by the magnetic sensor 13 is then delivered to readout circuitry comprising an amplifier 21 for amplification thus generating an amplified signal Ampl(t). This amplified signal Ampl(t) is synchronously demodulated by passing through a demodulator, e.g. a demodulating multiplier 43 with the modulation signal Mod(t) (in this case equal to sin at), resulting in an intermediate signal Mult(t), the intermediate signal Mult(t) being equal to:
Mult(t)=Nₙₚ I_{c} sin² at=Nₙₚ I_{c}. ½(1−cos 2at).

In a last step, the intermediate signal Mult(t) is sent through a low pass filter 44. The resulting signal Det(t) is then proportional to the number Nₙₚ of magnetic particles 12 present at the surface of the magnetic sensor strips 10.

By applying the detection method described in this embodiment of the present invention the low frequency magnetic noise as well as low frequency electronic noise, drift and offset are suppressed.

The method for the detection of magnetic particles 12 described above, is only one example and is not limiting to the invention. In other embodiments, the signal processing means may comprise other and/or additional functionalities.

It is to be understood that although preferred embodiments, specific constructions and configurations, as well as materials, have been discussed herein for devices according to the present invention, various changes or modifications in form and detail may be made without departing from the scope and spirit of this invention.

1. A sensor device (30) comprising:
at least one magnetic sensor element (13), and
at least one magnetic field generating means (42) for generating a magnetic field
wherein said at least one magnetic sensor element (13) comprises a plurality of N parallel magnetic sensor strips (10) and wherein the sensor device (30) furthermore comprises a voltage source (14) for applying a constant voltage over said at least one magnetic sensor element (13).

2. A sensor device (30) according to claim 1, the magnetic sensor element (13) being positioned on a substrate, and wherein the sensor device (30) furthermore comprises a signal processing means, positioned on the same substrate as the magnetic sensor element (13)

3. A sensor device (30) according to claim 1, wherein the magnetic field generating means (42) comprises a conductor (42) and an alternating current source (41) for generating an alternating current flowing through the conductor (42).

4. A sensor device (30) according to claim 2, wherein the magnetic sensor element (13), the signal processing means (24) and the magnetic field generating means (42) form an integrated circuit.

5. A sensor device (30) according to claim 1, wherein the magnetic sensor strips (10) are magneto-resistive sensor strips.

6. A sensor device (30) according to claim 5, wherein the magneto-resistive sensor strips are AMR, GMR or TMR sensor strips.

7. A sensor device (30) according to claim 2, wherein the signal processing means comprises at least one amplifier.

8. A sensor device (30) according to claim 7, wherein the signal processing means (24) furthermore comprises a linearizing circuit.

9. A sensor device (30) according to claim 1, the sensor device (30) comprising 2 magnetic sensor elements (13), each comprising N parallel magnetic sensor strips (10).

10. A sensor device (30) according to claim 1, the sensor device (30) furthermore comprising means for measuring a total current signal is in the at least one magnetic sensor element (13).

11. A method for the detection of the presence or determination of magnetic particles (12), the method comprising:
generating a magnetic field in the vicinity of a magnetic sensor element (13), the magnetic sensor element (13) comprising a plurality of N parallel magnetic sensor strips (10),
applying a constant voltage across said magnetic sensor element (13),
measuring a total signal current is in the magnetic sensor element (13).

12. Use of the sensor device (30) according to claim 1 for molecular diagnostics biological sample analysis, or chemical sample analysis.
